(19) United States
(12) Patent Application Publication
(10) Pub. No.: US 2025/0391481 A1
(43) Pub. Date: Dec. 25, 2025

(54) APPARATUS WITH BIAS-BASED CALIBRATION MECHANISM AND METHODS FOR OPERATING THE SAME

(71) Applicant: Micron Technology, Inc., Boise, ID (US)

(72) Inventors: Steve Kientz, Westminster, CO (US); Yang Liu, Melissa, TX (US)

(21) Appl. No.: 19/219,988

(22) Filed: May 27, 2025

Related U.S. Application Data
(60) Provisional application No. 63/662,771, filed on Jun. 21, 2024.

(51) Int. Cl. G11C 16/30; G11C 16/26; G11C 29/52

(52) U.S. Cl. CPC G11C 16/30; G11C 16/26; G11C 29/52; G11C 2207/2254

(57) ABSTRACT

Methods, apparatuses and systems related to calibrating a processing level used for one or more memory operations are described. An apparatus may include a calibration mechanism that iteratively updates the processing level based on obtaining feedbacks from using offset processing levels for the memory operations. The apparatus may apply a bias to one or more of the offset feedbacks in assessing the iteration stopping condition.

### CROSS-REFERENCE TO RELATED APPLICATION(S)

The present application claims priority to U.S. Provisional Patent Application No. 63/662,771, filed Jun. 21, 2024, the disclosure of which is incorporated herein by reference in its entirety.

This application contains subject matter related to an U.S. patent application by Yang Liu et al. titled “APPARATUS WITH PROCESSING LEVEL CALIBRATION MECHANISM AND METHODS FOR OPERATING THE SAME.” The related application is assigned to Micron Technology, Inc., and is identified as U.S. Patent Application No. 63/662,767, filed Jun. 21, 2024. The subject matter thereof is incorporated herein by reference thereto.

### TECHNICAL FIELD

The disclosed embodiments relate to devices, and, in particular, to semiconductor memory devices with bias-based calibration mechanisms and methods for operating the same.

### BACKGROUND

Memory systems can employ memory devices to store and access information. The memory devices can include volatile memory devices, non-volatile memory devices (e.g., flash memory employing “NAND” technology or logic gates, “NOR” technology or logic gates, or a combination thereof), or a combination device. The memory devices utilize electrical energy, along with corresponding threshold levels or processing/reading voltage levels, to store and access data. However, the capacity to store and retain charges degrade over time and usage, which can cause performance issues, such as degraded access time, data loss, increased errors, and/or catastrophic device failure.

### BRIEF DESCRIPTION OF THE DRAWINGS

The foregoing and other objects, features, and advantages of the disclosure will be apparent from the following description of embodiments as illustrated in the accompanying drawings, in which reference characters refer to the same parts throughout the various views. The drawings are not necessarily to scale, emphasis instead being placed upon illustrating principles of the disclosure.

FIG. 1 is a block diagram of a computing system in accordance with an embodiment of the present technology.

FIG. 2A, FIG. 2B, and FIG. 2C illustrate a first calibration mechanism in accordance with an embodiment of the present technology.

FIG. 3A and FIG. 3B illustrate a second calibration mechanism in accordance with an embodiment of the present technology.

FIG. 4 a flow diagram illustrating an example method of operating an apparatus in accordance with an embodiment of the present technology.

FIG. 5 is a schematic view of a system that includes an apparatus in accordance with an embodiment of the present technology.

### DETAILED DESCRIPTION

As described in greater detail below, the technology disclosed herein relates to an apparatus, such as memory systems, systems with memory devices, related methods, etc., for calibrating data access/management operations to account for shifts or changes in memory storage characteristics over time/usage. For example, the apparatus (e.g., a non-volatile memory device) can include a bias-based calibration mechanism configured to calibrate a processing level (e.g., a read level voltage) according to the memory storage characteristics.

In some embodiments, the processing level calibration mechanism can be configured to iteratively update a processing level until feedback metrics (e.g., error measures) for the processing level and one or more offset levels meet a stop condition that targets calibrating the processing level to a biased or an offset position different from a level that provides the lowest feedback level. For example, for each iteration, the apparatus can perform read operations using a current/base read level along with a first/negatively offset level and a second/positively offset level surrounding the current read level. The apparatus can determine feedback metrics associated with the various read levels. The apparatus can incrementally/iteratively adjust the base level and obtain and analyze the feedbacks to the adjusted levels until the stop condition is satisfied.

The apparatus can evaluate for the stop condition by computing/adding a feedback bias to one of the offset feedbacks (e.g., the first feedback) and then calculating a difference between the biased feedback value and the remaining one of the offset feedback. The apparatus can determine that the stop condition is satisfied when the calculated difference is below a predetermined feedback threshold. Additionally or alternatively, the stop condition can require both of the offset feedbacks to be above a base feedback level corresponding to the base read level

In stopping the calibration process using such stop condition, the iteratively updated read level can be established before it converges to a lowest error rate for the current physical trait of the storage cells. Accordingly, the apparatus can establish an improved read level voltage with less iterations than seeking for the lowest error rate. Further, the apparatus can prevent or reduce occurrences of over-correcting the read levels and exceeding past the lowest error rate. The prevention/reduction of overcorrection is further improved in tracking performances of data management groupings (e.g., block families, superblocks, or the like) or other types of group adjustments and/or irreversible changes.

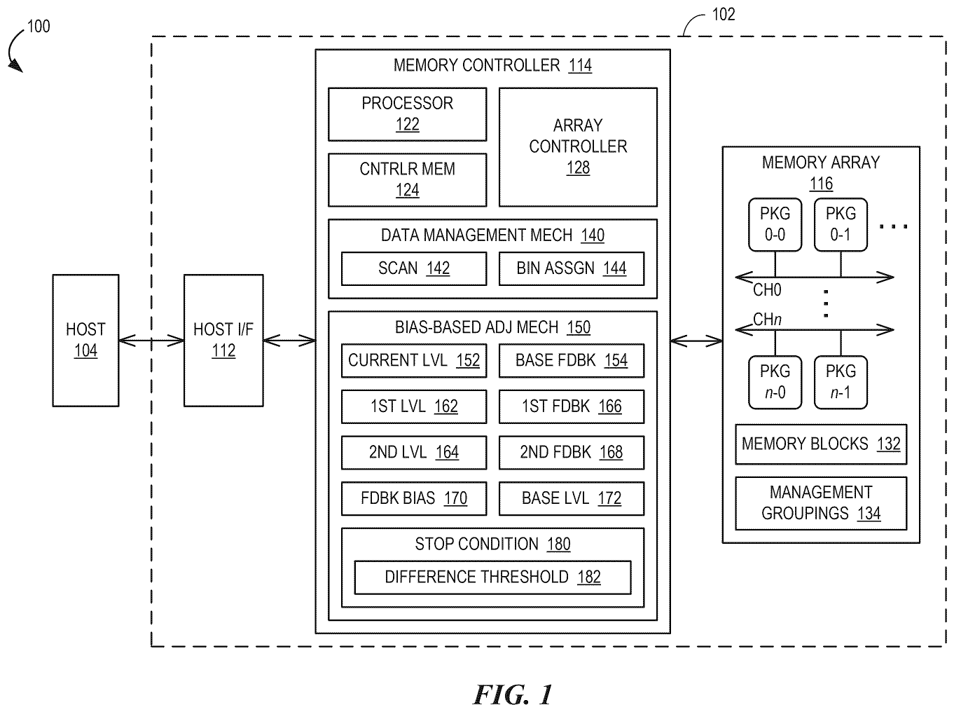

FIG. 1 is a block diagram of a computing system 100 in accordance with an embodiment of the present technology. The computing system 100 can include a personal computing device/system, a mobile device (e.g., a mobile/smart phone), a wearable device, a desktop computer, a laptop computer, a tablet computer, or the like. The computing system 100 can further include an enterprise or a commercial computing device/system, such as a mainframe computer, a server, a distributed or a cloud computing system, or the like.

The computing system 100 can include a memory system or subsystem 102 coupled to a host device 104. The host device 104 can include one or more processors that can write data to and/or read data from the memory system 102. For example, the host device 104 can include a central processing unit (CPU) controlling the operation of the computing system 100.

The memory system 102 can include circuitry configured to store data (via, e.g., write operations) and provide access to stored data (via, e.g., read operations). For example, the memory system 102 can include a persistent or non-volatile data storage system, such as a NAND-based Flash drive system or the like. In some embodiments, the memory system 102 can include a host interface 112 (e.g., buffers, transmitters, receivers, and/or the like) configured to facilitate communications with the host device 104. For example, the host interface 112 can be configured to support one or more host interconnect schemes, such as Universal Serial Bus (USB), Peripheral Component Interconnect (PCI), Serial AT Attachment (SATA), Universal Flash Storage (USF) protocol, or the like. The host interface 112 can receive commands, addresses, data (e.g., write data), and/or other information from the host device 104. The host interface 112 can also send data (e.g., read data) and/or other information to the host device 104.

The memory system 102 can further include a memory controller 114 and a memory array 116. The memory array 116 can include memory cells that are configured to store a unit of information. The memory controller 114 can be configured to control the overall operation of the memory system 102, including the operations of the memory array 116.

In some embodiments, the memory array 116 can include a set of storage devices or packages. Each of the storage devices can include a set of memory cells that each store data in a charge storage structure. The memory cells can include, for example, floating gate, charge trap, phase change, ferroelectric, magnetoresistive, and/or other suitable storage elements configured to store data persistently or semi-persistently. The memory cells can be one-transistor memory cells that can be programmed to a target state to represent information. For instance, electric charge can be placed on, or removed from, the charge storage structure (e.g., the charge trap or the floating gate) of the memory cell to program the cell to a particular data state. The stored charge on the charge storage structure of the memory cell can indicate a Vt of the cell. For example, a SLC can be programmed to a targeted one of two different data states, which can be represented by the binary units 1 or 0. Also, some flash memory cells can be programmed to a targeted one of more than two data states. Multi-level cells (MLCs) may be programmed to any one of four data states (e.g., represented by the binary 00, 01, 10, 11) to store two bits of data. Similarly, triple-level cells (TLCs) may be programmed to one of eight (i.e., 13) data states to store three bits of data, and quadruple-level cells (QLCs) may be programmed to one of 16 (i.e., 14) data states to store four bits of data.

Such memory cells may be arranged in rows (e.g., each corresponding to a word line) and columns (e.g., each corresponding to a bit line). The arrangements can further correspond to different groupings for the memory cells. For example, each word line can correspond to one or more memory pages. Also, the memory array 116 can include memory blocks 132 that each include a set of memory pages. In operation, the data can be written or otherwise programmed (e.g., erased) with regards to the various memory regions of the memory array 116, such as by writing to groups of pages and/or memory blocks 132. In NAND-based memory, a write operation often includes programming the memory cells in selected memory pages with specific data values (e.g., a string of data bits having a value of either logic 0 or logic 1). An erase operation is similar to a write operation, except that the erase operation re-programs an entire memory block or multiple memory blocks to the same data state (e.g., logic 0).

In some embodiments, the memory system 102 can further group the memory cells (e.g., the memory blocks 132) into data management groupings 134 for the purposes of managing the data stored therein or related data operations. The data management groupings 134 can correspond to one of many different granularities, containing only whole codewords, whole pages, whole super pages, or whole superblocks, or a combination thereof. For example, the data management groupings 134 can be based on superblocks that each include a set of data blocks spanning multiple dies/packages that are written in an interleaved fashion. Further the data management groupings 134 can include block families that each include memory cells that have been programmed within a specific time window. As such, the memory system 102 can use the data management groupings 134 that include blocks and/or superblocks that are expected to exhibit similar or correlated charge retention states or other data metrics.

While the memory array 116 is described with respect to the memory cells, it is understood that the memory array 116 can include other components (not shown). For example, the memory array 116 can also include other circuit components, such as multiplexers, decoders, buffers, read/write drivers, address registers, data out/data in registers, etc., for accessing and/or programming (e.g., writing) the data and for other functionalities.

As described above, the memory controller 114 can be configured to control the operations of the memory array 116. The memory controller 114 can include a processor 122, such as a microcontroller, special purpose logic circuitry (e.g., a field programmable gate array (FPGA), an application specific integrated circuit (ASIC), etc.), or other suitable processor. The processor 122 can execute instructions encoded in hardware, firmware, and/or software (e.g., instructions stored in controller-embedded memory 124) to execute various processes, logic flows, and routines for controlling operation of the memory system 102 and/or the memory array 116.

Further, the memory controller 114 can further include an array controller 128 that controls or oversees detailed or targeted aspects of operating the memory array 116. For example, the array controller 128 can provide a communication interface between the processor 122 and the memory array 116 (e.g., the components therein). The array controller 128 can function as a multiplexer/demultiplexer, such as for handling transport of data along serial connection to flash devices in the memory array 116.

In addition to storing and accessing data in the memory array 116, the memory controller 114, logic circuits within the memory array 116, corresponding firmware, or a combination thereof can manage the data stored in the memory array 116. For example, the memory system 102 can include a data management mechanism 140 (e.g., software, firmware, dedicated logic/circuit, or a combination thereof) configured to update one or more operating parameters to account for charge loss. The data management mechanism 140 can track charge loss, shift, or other disturbances within the memory array 116 (e.g., according to the data management groupings 134) and adjust the operating parameters. In effect, the data management mechanism 140 can use the tracked measures and the adjustments to allow the stored data to be accessed with acceptable (e.g., according to a predetermined threshold) Bit Error Rate (BER). Thus, the data management mechanism 140 can increase the duration between data refresh operations and the refresh rate by allowing acceptable access to otherwise disturbed data/charge levels.

In some embodiments, the data management mechanism 140 can be configured to implement a background scan 142 that evaluates the stored charge levels. The memory system 102 can implement the background scan 142 according to the memory blocks 132 and/or the data management groupings 134 (e.g., block families or superblocks). For example, the memory system 102 can read a portion of each superblock using a previously established read level and compute the corresponding error rate. When the error rate exceeds a predetermined threshold, the memory system 102 can estimate that a qualifying amount of charge has been lost and adjust the read level as a remedial response.

The management mechanism 140 can represent the charge loss and the read level adjustment using bin assignments 144. In other words, the memory system 102 can assign each block or data management grouping to a bin that uniquely corresponds to a read offset trim. As the stored data gets older and more charge is lost, the memory system 102 can sequentially assign the block/grouping to the next bin. The memory system 102 can refresh the blocks/groupings in the last bin.

As an illustrative example, newly written blocks can be assigned to Bin 0, which can correspond to a highest read level voltage setting (e.g., highest positive offset for a low base level voltage or zero offset for a high base level voltage). When the result of the background scan 142 (e.g., BER) exceeds a predetermined acceptability threshold, the memory system 102 can assign the corresponding block/grouping to the next bin, such as Bin 1, that corresponds to a reduced read level voltage (e.g., second highest positive offset for the low base level scheme or a first negative offset for a high base level scheme). Accordingly, the memory system 102 can change the bin assignment 144 for the corresponding block(s)/group. In some embodiments, the bin assignments 144 can be implemented using pointers that each correspond to a unique grouping and point to the assigned read levels or corresponding offset values.

In addition to the data management mechanism 140, the memory system 102 can include a bias-based calibration mechanism 150 (e.g., software, hardware circuit, firmware, or a combination thereof) configured to calibrate the processing level, such as the read level voltage, using a feedback bias 170 to accommodate changes in storage characteristics of the memory cells. For example, as memory cells age and charge storage capacity changes, the bias-based calibration mechanism 150 can calibrate the processing level accordingly. In some embodiments, the bias-based calibration mechanism 150 can calibrate the read level voltage used for the initial bin (e.g., without adjustment trim). The data management mechanism 140 can update the bin assignment 144, thereby adjusting or applying trims to the calibrated read level voltage according to the data retention time.

The bias-based calibration mechanism 150 can use a current processing level 152 (e.g., the read level voltage) for memory operations and track base processing feedback 154 (e.g., an error measure, such as a bit error count (BEC) or a BER) that corresponds to or results from using the current processing level 152. In calibrating the processing level, the bias-based calibration mechanism 150 can further perform memory operations using (1) a first offset level 162 that is below the current processing level 152, (2) a second offset level 164 that is above the current processing level 152, or both. The bias-based calibration mechanism 150 can track first offset feedback 166 and/or second offset feedback 168 that correspond to or result from using the first offset level 162 and/or the second offset level 164, respectively. In some embodiments, the bias-based calibration mechanism 150 can use the offset processing levels during the background scan 142 or a similar performance data gathering process. Further, the first offset level 162 and the second offset level 164 can be separated from the current processing level 152 by a predetermined offset level/voltage or a dynamically computed offset level/voltage.

When the tracked feedback levels are outside of a stop condition 180, the bias-based calibration mechanism 150 can iteratively change the current processing level 152, such as according to a predetermined direction (e.g., by decreasing the processing voltage). For example, the bias-based calibration mechanism 150 can initialize a base processing level 172 as the current processing level 152, compute the offset levels 162 and/or 164 based on the base processing level 172, and obtain feedbacks from implementing the base and one or more of the offset levels.

When the stop condition 180 is not met, the bias-based calibration mechanism 150 can iteratively decrease the base processing level 172 (e.g., a read level voltage) and repeat the process (e.g., compute offset levels, track the feedbacks, and evaluate stop condition). The bias-based calibration mechanism 150 can stop the iterative process and set the resulting base processing level 172 (e.g., the read level voltage that was being used to test the performance of the memory array 116) as a calibrated instance of the current processing level when the feedbacks satisfy the stop condition 180.

In determining whether the stop condition 180 is/has been met, the memory system 102 can combine the feedback bias 170 with one of the offset feedback. The feedback bias 170 can represent a predetermined or a (dynamically) computed magnitude configured to be applied to one of the offset feedback, thereby targeting a calibrated processing level that is different from (e.g., greater than) an optimum read level that minimizes the error rates for the tested or scanned memory cells. For example, the bias-based calibration mechanism 150 can be configured to apply the feedback bias 170 to the first offset feedback 166 to mimic a centered condition. The stop condition 180 can be configured to require a difference between (1) the biased feedback value (e.g., a combination of the first offset feedback 166 and the feedback bias 170) and (2) a remaining offset value (e.g., the second offset feedback) to be lower than a difference threshold 182. Additionally or alternatively, the stop condition 180 can require the biased feedback value and the remaining offset value to be higher than the base processing feedback 154.

In some embodiments, the memory system 102 can dynamically compute/adjust the feedback bias 170. For example, the memory system 102 can compute the feedback bias 170 according to a predetermined equation or process that uses codeword measurement variations, a different between the first offset feedback 166 and the second offset feedback 168 for one or more addresses (e.g., across multiple stored data within the same bin), DAC advance rate, and/or other similar measurements/projections. In dynamically computing, the memory system 102 can compute the feedback bias 170 anew per each calibration session, per each calibration iteration, and/or the like using real-time parameters. Details regarding the bias-based calibration mechanism 150 are described further below.

The magnitude of offset can be pre-characterized on the NAND to reflect the desired shift. The memory system 102 can add a fixed bit error count (BEC) to the left RSO sample to create an implicit bias. This bias can naturally adjust the centering of the valley based on the measured CW BEC counts, such as through the centering algorithm. Pre-characterization can reveal a linear, or quadratic or other fit without performing an active fitting at the device level during operation.

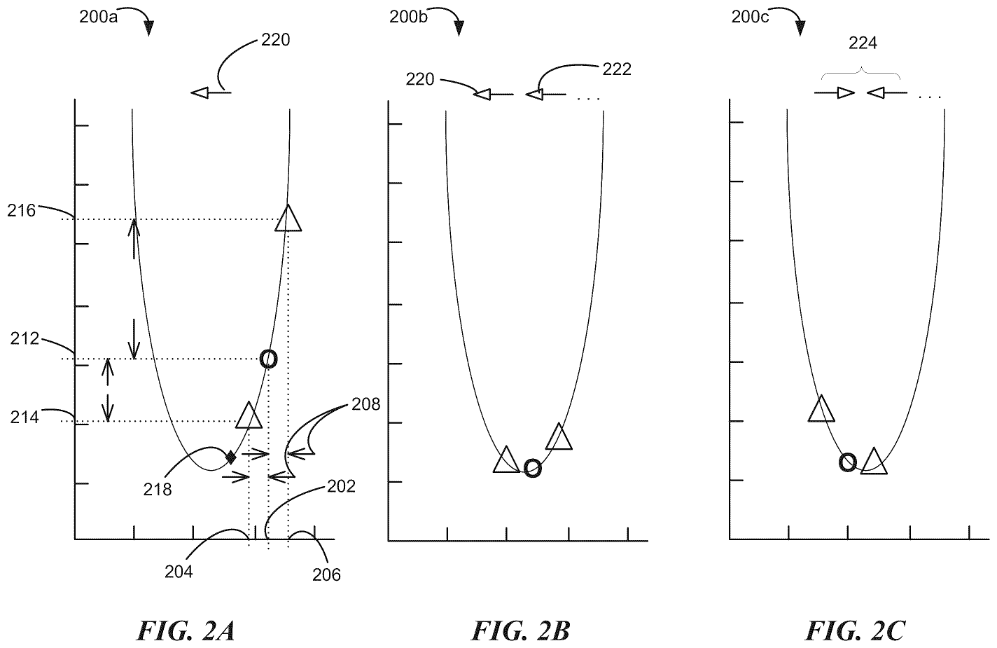

FIG. 2A, FIG. 2B, and FIG. 2C illustrate a first calibration mechanism in accordance with an embodiment of the present technology. FIG. 2A, FIG. 2B, and FIG. 2C can each show a storage characteristic 200 of a given memory cell at different points/iterations for the first calibration mechanism. FIG. 2A can show a first stage or an initial starting point 200a before implementing or iterating through the first calibration mechanism. FIG. 2B can show a later stage/iteration 200b for the first calibration mechanism, and FIG. 2C can show a stage or an iteration 200c immediately following the stage/iteration 200b, an end stage/iteration, or the like.

Referring to FIG. 2A, FIG. 2B, and FIG. 2C together, the storage characteristic 200 can be represented as a pattern of error measures (vertical axes), such as the BEC/BER, that result from using different read levels (horizontal axes) to read the same amount of charges stored in the corresponding memory cell. The represented pattern can have a concave curve with a bottom or a lowest error measure that results or would result from implementing an optimal read level voltage. In other words, the current storage characteristic 200 can have to an optimal read level voltage that produces the lowest error measure.

The first calibration mechanism can be configured to set a current read level 202 (e.g., the current processing level 152 of FIG. 1) at or centered around the bottom of the concave trace (e.g., at or within a threshold range from the optimal read level voltage). In some embodiments, the first calibration mechanism can compute a first offset level 204 and a second offset level 206 according to a read level offset 208 (e.g., a predetermined or a dynamically computed voltage magnitude). The first offset level 204 (e.g., the first offset level 162 of FIG. 1) can correspond to an alternative or a tested read level voltage that is lower than the current read level 202 by the read level offset 208. Similarly, the second offset level 206 (e.g., the second offset level 164 of FIG. 1) can correspond to an alternative or a tested read level voltage that is higher than the current read level 202 by the read level offset 208. As described above, the first calibration mechanism can track base error feedback 212, first offset feedback 214, and second offset feedback 216 (e.g., the error measures, such as the BEC/BER) based on using the current read level 202, the first offset level 204, and the second offset level 206, respectively.

As an illustrative example, the storage characteristic 200 can shift over time and usage, thus causing the illustrated curve to shift (e.g., to the left as illustrated in FIG. 2A), and increase the error rate for the current read level 202. The first/initial starting point 200a can illustrate the effect of the current read level 202 after the shift in storage characteristic 200. Accordingly, the base error feedback 212 can be higher than the initial error feedback that occurred before the shift.

The memory system 102 of FIG. 1 can trigger the first calibration mechanism can based on the increase in the base error feedback 212 (e.g., according to a predetermined trigger threshold), the usage rate or the number of implemented operations, the deployment/power-on time, or a combination thereof. Once triggered, the first calibration mechanism can compute and implement the first offset level 204 and the second offset level 206. Accordingly, the first calibration mechanism can track the base error feedback 212, the first offset feedback 214, and the second offset feedback 216, such as during the background scan 142 of FIG. 1.

After a predetermined period or after gathering at least a predetermined number of feedback samples, the first calibration mechanism can evaluate the feedback and determine whether to adjust the current read level 202. For example, the first calibration mechanism can compute the difference(s) between (1) the base error feedback 212 and the first offset feedback 214, (2) the base error feedback 212 and the second offset feedback 216, (3) the first offset feedback 214 and the second offset feedback 216, or a combination thereof. The first calibration mechanism can compute the magnitude of the differences, the polarity or the slope associated with the differences, and/or the like for comparison purposes.

In some embodiment, the first calibration mechanism can determine an adjustment direction 220 based on comparing the feedbacks. For example, the first calibration mechanism can determine the adjustment direction 220 for decreasing the current read level 202 when (1) the first offset feedback 214 is lower than the base error feedback 212, (2) the second offset feedback 216 is higher than the base error feedback 212, or a combination thereof. Likewise, the calibration mechanism can determine the adjustment direction 220 for increasing the current read level 202 when (1) the first offset feedback 214 is higher than the base error feedback 212, (2) the second offset feedback 216 is lower than the base error feedback 212, or a combination thereof. The first calibration mechanism can adjust the current read level 202 according to the adjustment direction 220.

The first calibration mechanism can adjust the current read level 202 according to a triggering condition. For example, the first calibration mechanism can adjust the current read level 202 when the base error feedback 212 is greater than a triggering threshold, when the feedback differences have opposing signs/polarities in the differences (e.g., one of the first offset feedback 214 and the second offset feedback 216 is below the base error feedback 212 and the other above), and/or the like.

In some embodiments, the first calibration mechanism can adjust base processing level 172 according to a predetermined step (e.g., the read level offset 208 or another like read level magnitude). Alternatively or additionally, the first calibration mechanism can adjust the base processing level 172 (e.g., the adjustment magnitude) according to a predetermined computation and the feedback difference(s). For example, the memory system 102 can compute a vector 218 for the adjustment in the processing level 172 based on a difference between the feedbacks 212, 216, and/or 216. In one or more embodiments, the vector 218 can be computed as a maximum between (1) a scalar (e.g., 1.0) and (2) a magnitude of the difference in feedbacks 214 and 216 (e.g., left and right values) that is normalized by a predetermined value (e.g., a predetermined maximum offset value/function). The memory system 102 can use, such as by adding, the vector 218 to adjust the base processing level 172 for the next iteration.

After adjusting, the first calibration mechanism can initiate a different/subsequent iteration and compute/update the first offset feedback 214 and/or the second offset feedback 216 based on the base processing level 172. For the next iteration, the first calibration mechanism can track the track the base error feedback 212, the first offset feedback 214, and/or the second offset feedback 216 according to the updated read level voltages. The first calibration mechanism can iteratively update the base processing level 172 as described above. Further, the first calibration mechanism can track a previous adjustment 222 (e.g., a previous instance of the adjustment direction 220, a previous instance of the base processing level 172, a previously applied adjustment amount, and/or the like from the immediately preceding iteration).

When the storage characteristic 200 shifts to the left for the initial starting point 200a, the first calibration mechanism can iteratively decrease the base processing level 172. Based on the iterative adjustment(s), the first calibration mechanism can reach the later stage/iteration 200b when the base processing level 172 is closer to the optimal read level voltage (e.g., near or about the lowest point of the curve).

The first calibration mechanism can iterate and adjust the base processing level 172 until the stop condition 180 of FIG. 1 is satisfied. For example, the first calibration mechanism can be configured to stop the iteration according to a centered condition 224 configured to detect the processing level reaching the optimal read level voltage or within a threshold range thereof. The centered condition 224 can correspond to a dither in the adjustment direction 220, such as when the adjustment direction 220 for the current iteration differs from the previous adjustment 222 from the preceding iteration. The dither can correspond to the read level passing the optimal read level voltage between the current iteration and the preceding iteration. In some embodiments, the first calibration mechanism can use the base processing level 172 from the current iteration, the previous iteration, or a combination thereof (e.g., an average or a midpoint thereof) as a calibrated or an updated instance of the current processing level 152.

Additionally or alternatively, the centered condition 224 can correspond to one of the first offset feedback 214 and the second offset feedback 216 rising above the base error feedback 212. Such centered condition 224 can correspond to the corresponding offset level moving past the inflection point of the storage characteristic 200 as illustrated in FIG. 2B. Accordingly, the centered condition 224 can represent the base processing level 172 or one of the offset levels being located at or within a threshold range from the center/inflection point of the storage characteristic 200. Thus, the first calibration mechanism can be configured to calibrate the current processing level 152 to be at or within a threshold range from (e.g., closest to) the optimized read level voltage that corresponds to the lowest error feedback for the tested memory cell(s).

In other embodiments, the stop condition 180 can be based on a difference between the first offset feedback 166 and the second offset feedback 168 (e.g., with the feedback bias 170 applied). The memory system 102 can be configured to stop the calibration when the difference between first offset feedback 166 and the second offset feedback 168 is less than a predetermined stop threshold.

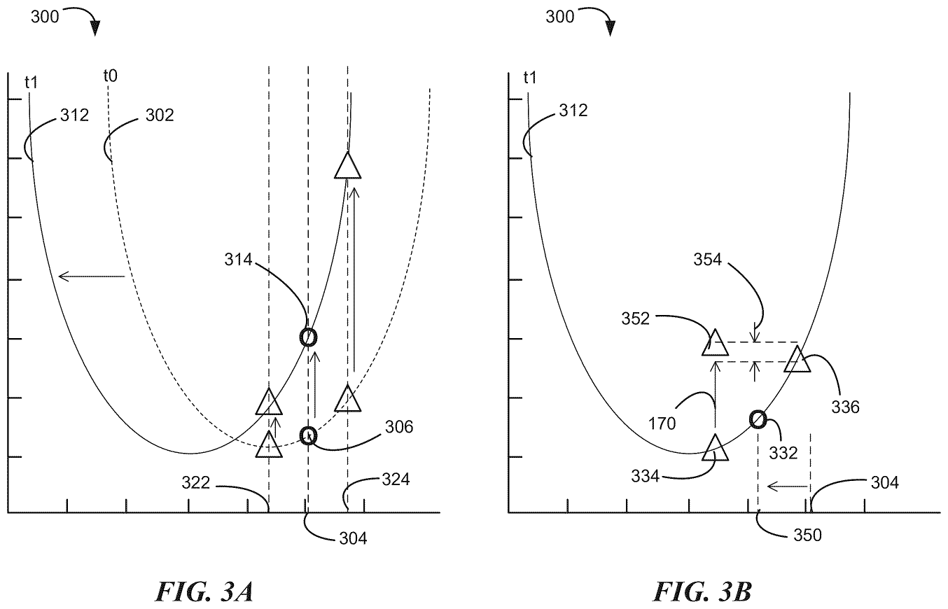

FIG. 3A and FIG. 3B illustrate a second calibration mechanism 300 (e.g., an instance of the bias-based calibration mechanism 150 of FIG. 1) in accordance with an embodiment of the present technology. To illustrate the second calibration mechanism 300, FIG. 3A can show an initial iteration of the second calibration mechanism 300, and FIG. 3B can show a subsequent or a final iteration of the second calibration mechanism 300.

For context, FIG. 3A shows a previous storage characteristic 302 (e.g., at t0) and a corresponding previous read level 304. When the tested memory cell(s) had the previous storage characteristic 302, the previous read level 304 produced previous feedback 306 (e.g., an error measure, such as a BEC/BER). However, after time and/or usage of the memory cell(s), the storage characteristics can change or degrade to a shifted characteristic 312. The change between the previous storage characteristic 302 to the shifted characteristic 312 can correspond a leftward movement that results in an increase in the error rate for the previous read level 304. For the shifted characteristic 312, using the previous read level 304 for read operations can produce unadjusted feedback 314 that is higher than the previous feedback 306.

In calibrating the processing level (e.g., the read level voltage), the calibration mechanism 300 can be configured to compute a first offset level 322 and/or a second offset level 324 based on the previous read level 304. For example, the calibration mechanism 300 can compute the first offset level 322 below the previous read level 304, the second offset level 324 above the previous read level 304, or a combination thereof. In some embodiments, the calibration mechanism 300 can compute the first offset level 322 and/or the second offset level 324 according to a predetermined or a dynamically computed magnitude (e.g., the read level offset 208 of FIG. 2), a predetermined equation, one or more of the feedback levels, or a combination thereof. Further, the calibration mechanism 300 can track the feedback from implementing the various levels. For example, the calibration mechanism 300 can track first offset feedback 334 and/or second offset feedback 336 corresponding to the first offset level 322 and the second offset level 324, respectively, in addition to the unadjusted feedback 314.

The calibration mechanism 300 can be configured to adjust the processing level (e.g., the read level voltage) based on one or more of the feedback measures. For example, the calibration mechanism 300 can trigger an adjustment when the first offset level 322, the second offset level 324, and/or the unadjusted feedback 314 fails to meet the stop condition 180 of FIG. 1. The calibration mechanism 300 can adjust the processing level to generate a base read level 350, such as according to the adjustment direction (e.g., decreasing voltage). For example, the calibration mechanism 300 can adjust the read level voltage based on decreasing the read level voltage. The calibration mechanism 300 can similarly adjust or recompute the first offset level 322 and/or the second offset level 324 according to the base read level 350. Further, the calibration mechanism 300 can implement the adjusted levels and obtain the corresponding feedbacks; the calibration mechanism 300 can compute base feedback 332 based on using the base read level 350.

The calibration mechanism 300 can iteratively adjust (e.g., decrease) the processing level, obtain the feedbacks, and evaluate the feedbacks as described above until the stop condition 180. In assessing for the stop condition 180, the calibration mechanism 300 can compute biased feedback 352 based on combining, such as by adding, one of the offset feedbacks (e.g., the first offset feedback 334) with the feedback bias 170. The calibration mechanism 300 can evaluate the biased feedback 352 instead of the non-biased value (e.g., the first offset feedback 334) in assessing the stop condition 180.

In some embodiments, the feedback bias 170 can be a predetermined/fixed value (e.g., a fixed error count, a fixed percentage increase, or the like). Moreover, in some embodiments, the feedback bias 170 can be applied to every left read sample offset. In other embodiments, the feedback bias 170 can be dynamically computed based on the first, second, and/or base feedbacks and/or the base processing level 172. For example, the feedback bias 170 can be inversely proportional to a difference between one or more of the offset feedback and/or applied when the difference between the one or more offset feedback is within a threshold range. Thus, the feedback bias 170 can have a greater influence when the base processing level 172 is within a targeted location. Also, for example, the feedback bias 170 can have different magnitudes based on the base processing level 172 so as to provide different degrees of influence/adjustments as the memory cells degrade. Moreover, the feedback bias 170 can be dynamically computed based on measurements (e.g., variations in measurements) associated with code words, the DAC advance rate expected from background scans, and/or the like.

As described above, the calibration mechanism 300 can detect the stop condition 180 when the offset difference 354 is less than the difference threshold 182. Additionally or alternatively, the calibration mechanism 300 can detect the stop condition 180 the biased feedback 352, the remaining feedback (e.g., the second offset feedback 336), or both are greater than the base feedback 332. Accordingly, the calibration mechanism 300 and the stop condition 180 can be configured to stop the iteration when the base processing level 172 reaches a location different from a lowest point of the shifted characteristic 312. For example, the calibration mechanism 300 can be configured to iteratively decrease the read voltage level and use the feedback bias 170 on the first offset feedback 334 such that the read voltage level is calibrated to a level higher than (e.g., to the right of) the level that minimizes the resulting error. The feedback bias 170 can be controlled to control a separation between the calibrated current processing level 152 of FIG. 1 (e.g., where the iterative adjustments stop) and the optimal read voltage level that minimizes the feedback measure.

In some embodiments, the calibration mechanism 300 can leverage the centered condition 224 (e.g., the dither condition) of FIG. 2 along with the biased feedback 352 to detect the stop condition 180. Using the biased feedback 352 instead of the first offset feedback 334, the calibration mechanism 300 can leverage the centered condition 224 to achieve the calibration target higher than (e.g., to the right of) the lowest-error read voltage level.

In calibrating the read level voltage to a value different from and within a range from the lowest-error read voltage level using the feedback bias 170, and the biased feedback 352 instead of the first offset feedback 334, the calibration mechanism 300 can address measurement variations across various data management groupings 134 of FIG. 1, across the bin assignments 144 of FIG. 1, or both. Thus, the calibration mechanism 300 can improve the accuracy for the bin assignments 144 and prevent/reduce over corrections, which may be irreversible. Moreover, the calibration mechanism 300 can leverage the centered condition 224 or other existing calibration mechanisms while shifting the calibration target higher/to the right.

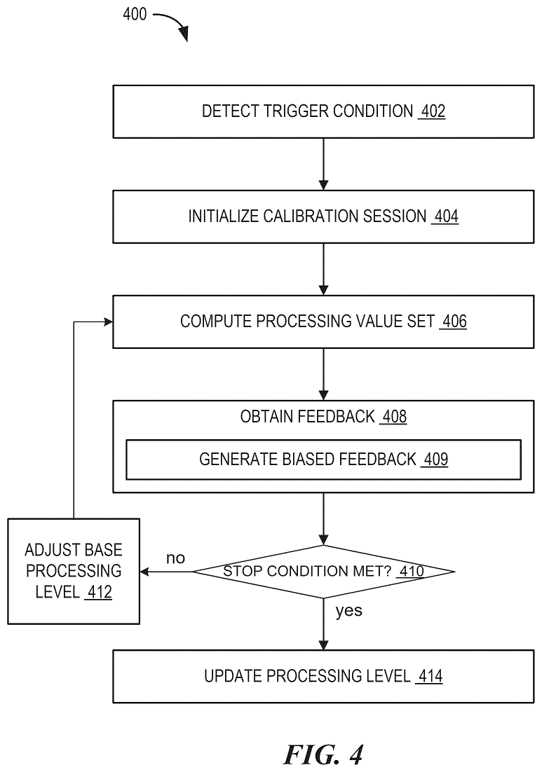

FIG. 4 a flow diagram illustrating an example method 400 of operating an apparatus (e.g., the memory system 102 of FIG. 1, the processor 122 of FIG. 1) in accordance with an embodiment of the present technology. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. The method 400 can correspond to implementing the bias-based calibration mechanism 150 of FIG. 1, such as the calibration mechanism 300 of FIG. 3. For example, the method 400 can correspond to adjusting a processing level, such as the current processing level 152 of FIG. 1, the previous read level 304 of FIG. 3A, the base read level 350 of FIG. 3B (e.g., the read level voltage), etc.

Although shown in a particular sequence or order, unless otherwise specified, the order of the operations can be modified. Thus, the illustrated embodiments should be understood only as examples, and the illustrated operations can be performed in a different order, while some operations can be performed in parallel. Additionally, one or more operations can be omitted in some embodiments. Thus, not all illustrated operations are required in every embodiment, and other process flows are possible.

At block 402, the apparatus can detect a trigger condition for implementing the bias-based calibration mechanism 150 to calibrate a processing level (e.g., a read voltage level) used in one or more types of memory operations, such as read operations. The apparatus can detect the trigger condition based on a tracked usage measure, such as an elapsed time since the last calibration or a number of implemented memory operations, a feedback measure (e.g., an error measure, such as the BEC, from using the processing level), or a combination thereof. As an illustrative example, the apparatus can use the previous read level 304 for implementing read operations and track the resulting base feedback 332 (e.g., the BEC). When the base feedback 332 reaches a predetermined triggering error threshold, the apparatus can initiate the bias-based calibration mechanism 150.

At block 404, the apparatus can initialize one or more values used for the bias-based calibration mechanism 150. For example, the apparatus can set the base read level 350 as the previous read level 304. In addition, the apparatus can initialize the previous adjustment 222 of FIG. 2B, offset feedbacks, or the like for the calibration session.

In implementing the calibration session, the apparatus can compute a set of processing values/levels as illustrated in block 406. For example, the apparatus can compute at least one offset processing level, such as the first offset level 322 of FIG. 3A, the second offset level 324 of FIG. 3A, or both, based on the processing voltage (e.g., the base read level 350). In some embodiments, the at least one offset processing level can be computed using the read level offset 208 of FIG. 2A that corresponds to a predetermined offset magnitude. In other embodiments, the apparatus can dynamically compute the read level offset 208 using feedbacks (e.g., error metrics, such as for the base feedback 332, the first offset feedback 334 of FIG. 3A, the second offset feedback 336 of FIG. 3A, etc. from the previous iteration). For example, the apparatus can compute the read level offset 208 according to a difference between the feedback threshold 182 of FIG. 3A and the base feedback 332, the first offset feedback 334 of FIG. 3A, the second offset feedback 336, or a combination thereof.

At block 408, the apparatus can obtain a set of feedback (e.g., error measures, such as the BECs/BERs) from using the set of processing values/levels for one or more types of memory operations. After computing the processing value set, the apparatus can implement memory operations, such as read operations or Read Sample Offset (RSO) operations, using the processing value set. For example, the apparatus can obtain (1) the base feedback 332 based on using the base read level 350, (2) the first offset feedback 334 based on using the first offset level 322, and/or (3) the second offset feedback 336 based on using the second offset level 324. The apparatus can obtain the feedback for a predetermined duration, across a minimum number of memory operations, or a combination thereof.

At block 409, the apparatus can generate biased feedback (e.g., the biased feedback 352 of FIG. 3B) based on combining one of the offset feedback with the feedback bias 170 of FIG. 1. In some embodiments, the apparatus can compute the feedback bias 170, such as based on collecting codeword measurements (e.g., error rates) and calculating variations thereof. Alternatively or additionally, the apparatus can compute the feedback bias 170 based on the bin assignments 144 of FIG. 1 (e.g., differences in the left biased feedback values and the right feedback values within/across the same bin). The apparatus can further compute the feedback bias 170 based on estimating the current storage characteristic (e.g., shapes associated with the characteristics 302 of FIG. 3A and 312 of FIG. 3B) of the memory array/block, such as using total power-on time, feedback values, historical data, or a combination thereof.

The apparatus can add the feedback bias 170 to the first offset feedback 334 (e.g., the left error count for the RSO implementation) to generate the biased feedback 352. The apparatus can further replace the first offset feedback 334 with the biased feedback 352 or use the biased feedback 352 instead of the first offset feedback 334 for subsequent operations. The apparatus can use a fixed value for the feedback bias 170 or dynamically compute/adjust the feedback bias 170 as described above.

At decision block 410, the apparatus can determine whether a stop condition (e.g., the stop condition 180 of FIG. 1) for the iterative calibration has been satisfied. For example, the apparatus can compute the offset difference 354 of FIG. 3B and determine whether the offset difference is 354 within or less than the difference threshold 182 of FIG. 1. Also, the apparatus can determine whether the biased feedback 352, the second offset feedback 336, or both are greater than the base feedback 332. Additionally or alternatively, the apparatus can determine the adjustment direction 220 of FIG. 2A using the biased feedback 352 and determine the stop condition based on detecting the centered condition 224 of FIG. 2B, such as a dither in the adjustment direction 220 or a difference between the adjustment direction 220 and the previous adjustment 222 of FIG. 2B. In some embodiments, the apparatus can effectively determine whether the base processing level is within a threshold range from the read level voltage that minimizes the error counts as described above.

When the stop condition is not met, the apparatus can adjust the base processing level (e.g., the base read level 350) as illustrated in block 412. In some embodiments, the base read level 350 can be adjusted according to a predetermined increment (e.g., the read level offset 208, a trim value, or a different magnitude), a dynamically computed increment, the adjustment direction 220 of FIG. 2, or a combination thereof. For the dynamically computed increment, the apparatus can use the difference between the obtained feedback values and the feedback threshold 182 to compute the adjustment increment. For example, the apparatus can compute a larger increment when the difference between the error rate(s) and the stopping error threshold are greater.

After adjusting the base processing level, the apparatus can implement a subsequent iteration for the bias-based calibration mechanism 150 as illustrated by the feedback loop to block 406. Accordingly, the apparatus can iteratively adjust the processing voltage (e.g., the base read level 350) until the stop condition is met.

When the stop condition is met, the apparatus can update the processing level (e.g., the current processing level 152) with the base read level 350 as illustrated in block 414. Thus, the apparatus can update the processing level based on reaching a targeted calibration level using the feedback bias 170.

In other words, the apparatus can lower the processing level to the targeted calibration level (e.g., higher and within a range of the inflection point in the shifted/current characteristic 312) using the feedback bias 170 and without attempting to find the level that provides the lowest error rate.

In updating the processing level, the apparatus can end the calibration session, and the calibrated processing level can be used for subsequent memory operations. For example, for the data management mechanism 140, the current processing level 152 can provide the base, such as for Bin 0, and additional trims can be applied thereto according to the estimated charge loss. In other words, the current processing level 152 can be used to read the data management groupings 134 of FIG. 1 in Bin 0. As the data management groupings 134 are assigned to different bins (e.g., representative of different amounts of charge loss) based on the charge/data retention time, the apparatus can apply additional trim to adjust, such as for lowering, the utilized read level voltage from the current processing level 152.

Thus, the bias-based calibration mechanism 150 can provide optimized processing levels and reduce time/resources used for other management mechanisms. For example, the calibrated read level voltage can reduce the necessary resources and/or the error rates associated with the data management mechanism 140. Further, since the data management mechanism 140 applies the trim to larger groupings of the memory cells (e.g., the data management groupings 134) than the subset of memory cells used for the calibration, the bias-based calibration mechanism 150 using the feedback bias 170 can reduce the errors associated with overshooting the optimized level for other non-tested cells within the larger grouping.

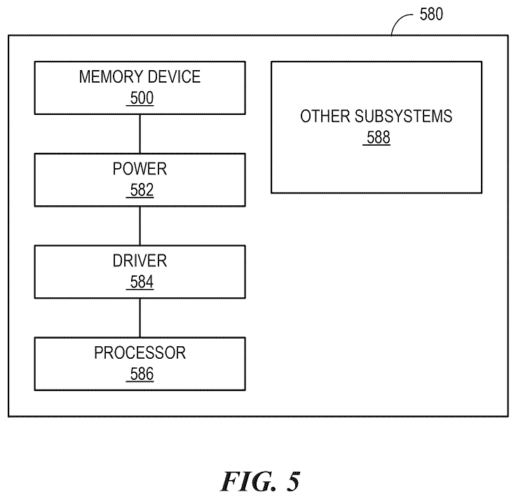

FIG. 5 is a schematic view of a system that includes an apparatus in accordance with embodiments of the present technology. Any one of the foregoing apparatuses (e.g., memory devices) described above with reference to FIGS. 1-6 can be incorporated into any of a myriad of larger and/or more complex systems, a representative example of which is system 580 shown schematically in FIG. 5. The system 580 can include a memory device 500, a power source 582, a driver 584, a processor 586, and/or other subsystems or components 588. The memory device 500 can include features generally similar to those of the apparatus described above with reference to one or more of the FIGS, and can therefore include various features for performing a direct read request from a host device. The resulting system 580 can perform any of a wide variety of functions, such as memory storage, data processing, and/or other suitable functions. Accordingly, representative systems 580 can include, without limitation, hand-held devices (e.g., mobile phones, tablets, digital readers, and digital audio players), computers, vehicles, appliances and other products. Components of the system 580 may be housed in a single unit or distributed over multiple, interconnected units (e.g., through a communications network). The components of the system 580 can also include remote devices and any of a wide variety of computer readable media.

From the foregoing, it will be appreciated that specific embodiments of the technology have been described herein for purposes of illustration, but that various modifications may be made without deviating from the disclosure. In addition, certain aspects of the new technology described in the context of particular embodiments may also be combined or eliminated in other embodiments. Moreover, although advantages associated with certain embodiments of the new technology have been described in the context of those embodiments, other embodiments may also exhibit such advantages and not all embodiments need necessarily exhibit such advantages to fall within the scope of the technology. Accordingly, the disclosure and associated technology can encompass other embodiments not expressly shown or described herein.

In the illustrated embodiments above, the apparatuses have been described in the context of NAND Flash devices. Apparatuses configured in accordance with other embodiments of the present technology, however, can include other types of suitable storage media in addition to or in lieu of NAND Flash devices, such as, devices incorporating NOR-based non-volatile storage media (e.g., NAND flash), magnetic storage media, phase-change storage media, ferroelectric storage media, dynamic random access memory (DRAM) devices, etc.

The term “processing” as used herein includes manipulating signals and data, such as writing or programming, reading, erasing, refreshing, adjusting or changing values, calculating results, executing instructions, assembling, transferring, and/or manipulating data structures. The term data structure includes information arranged as bits, words or code-words, blocks, files, input data, system-generated data, such as calculated or generated data, and program data. Further, the term “dynamic” as used herein describes processes, functions, actions or performance occurring during operation, usage, or deployment of a corresponding device, system or embodiment, and after or while running manufacturer's or third-party firmware. The dynamically occurring processes, functions, actions or performances can occur after or subsequent to design, manufacture, and initial testing, setup or configuration.

The above embodiments are described in sufficient detail to enable those skilled in the art to make and use the embodiments. A person skilled in the relevant art, however, will understand that the technology may have additional embodiments and that the technology may be practiced without several of the details of the embodiments described above with reference to one or more of the FIGS. described above.

I/We claim:

1. A memory device, comprising:
a memory array including memory cells configured to store charges representative of stored data; and
a logic circuit coupled to the memory array and configured to:
implement one or more memory operations for stored data using a processing voltage;
iteratively calibrate the processing voltage using a feedback bias, wherein, for each iteration, the logic circuit is configured to:
compute (1) a first offset processing level lower than the processing voltage and (2) a second offset processing level higher than the processing voltage;
obtain a set of feedback values that include at least (1) a first offset feedback based on using the first offset processing level and (2) a second offset feedback based on using the second offset processing level;
compute a biased feedback based on combining the feedback bias with the first offset feedback; and
adjust the processing voltage based on the biased feedback and the second offset feedback.

2. The memory device of claim 1, wherein the processing voltage is a read level voltage used for reading the stored data.

3. The memory device of claim 1, wherein the logic circuit is configured to iteratively calibrate the processing voltage until a stop condition is satisfied, wherein the stop condition includes (1) a difference between the biased feedback and the second offset feedback being less than a difference threshold or (2) a change in adjustment directions across iterations.

4. The memory device of claim 1, wherein the logic circuit is configured to:
compute an adjustment vector based on a difference between the biased feedback and the second offset feedback per iteration; and
adjust the processing voltage according to the adjustment vector for a next iteration.

5. The memory device of claim 4, wherein the logic circuit is configured to compute the adjustment vector based on normalizing the difference according to a maximum offset function and (1) an iteration count, (2) a calibration session count, (3) a current instance the processing voltage, (4) a total runtime of the memory device, or a combination thereof.

6. The memory device of claim 1, wherein the logic circuit is configured to dynamically compute the feedback bias for each calibration session and/or each calibration iteration.

7. The memory device of claim 6, wherein the logic circuit is configured to dynamically compute the feedback bias based on one or more variations in code word measurements.

8. The memory device of claim 6, wherein:
the memory cells are arranged according to memory blocks; and
the logic circuit is configured to:
assign a bin assignment to a set of memory blocks according to a write time of data stored therein; and
dynamically compute the feedback bias based on differences between the first and second offset feedbacks for two or more blocks within the set of memory blocks having the same bin assignment.

9. The memory device of claim 6, wherein the logic circuit is configured to:
implement a background scan to evaluate stored charge levels;
update a bin assignment to a set of memory blocks according to the background scan, wherein the bin assignment corresponds to a read adjustment to the processing voltage in reading from the set of memory blocks; and
dynamically compute the feedback bias based on the read adjustment.

10. The memory device of claim 6, wherein the logic circuit is configured to:
estimate a pattern between different values of the processing voltage and corresponding feedback values wherein the pattern is represented by data from previous calibration iterations, data from previous calibration sessions, total active time of the memory device, a number of memory access operations, or a combination thereof; and
dynamically compute the feedback bias based on the estimated pattern.

11. An apparatus, comprising:
a host interface configured to communicate with an upstream host device;
a downstream interface configured to communicate with memory cells that are configured to store charges representative of stored data; and
a logic circuit coupled to the host and downstream interfaces and configured to iteratively calibrate a read level voltage using a feedback bias, wherein, for each iteration, the logic circuit is configured to:
compute (1) a first offset level lower than the read level voltage and (2) a second offset level higher than the read level voltage;
obtain a set of feedback values that include at least (1) a first offset feedback based on using the first offset level and (2) a second offset feedback based on using the second offset level;
compute a biased feedback based on combining the feedback bias with the first offset feedback; and
adjust the read level voltage based on the biased feedback and the second offset feedback.

12. The apparatus of claim 11, wherein the logic circuit is configured to iteratively calibrate the read level voltage until a stop condition is satisfied, wherein the stop condition includes (1) a difference between the biased feedback and the second offset feedback being less than a difference threshold or (2) a change in adjustment directions across iterations.

13. The apparatus of claim 11, wherein the logic circuit is configured to:
compute an adjustment vector based on a difference between the biased feedback and the second offset feedback per iteration; and
adjust the read level voltage according to the adjustment vector for a next iteration.

14. The apparatus of claim 11, wherein the logic circuit is configured to dynamically compute the feedback bias for each calibration session and/or each calibration iteration based on (1) one or more variations in code word measurements corresponding to data stored in the memory cells, (2) a write time of the data stored within the memory cells, (3) a read adjustment updated and applied to the read level voltage in reading the stored data, or a combination thereof.

15. The apparatus of claim 14, wherein the logic circuit is configured to:
estimate a pattern between different values of the read level voltage and corresponding feedback values wherein the pattern is represented by data from previous calibration iterations, data from previous calibration sessions, total active time of the memory device, a number of memory access operations, or a combination thereof, wherein the pattern includes a sampled minimum level corresponding to a lowest error rate;
dynamically compute the feedback bias based on the estimated pattern; and
using the feedback bias, stop the iterative calibration while the read level voltage is above the sampled minimum level.

16. A method of operating a memory device that includes memory cells configured to store charges representative of stored data, the method comprising:
iteratively calibrating a read level voltage using a feedback bias,
wherein the read level voltage is used to read the stored data, and
wherein the read level voltage is calibrated by:
computing a first offset level lower than the read level voltage;
computing a second offset level higher than the read level voltage;
obtaining a first error measure based on using the first offset level;
obtaining a second error measure based on using the second offset level;
computing a biased error measure based on combining the feedback bias with the first error measure; and
adjusting the read level voltage based on the biased feedback and the second offset feedback.

17. The method of claim 16, wherein the read level voltage is iteratively adjusted until a difference between the biased feedback and the second offset feedback is less than a difference threshold.

18. The method of claim 16, further comprising:
computing an adjustment vector based on a difference between the biased feedback and the second offset feedback per iteration; and
adjusting the read level voltage according to the adjustment vector for a next iteration.

19. The method of claim 16, further comprising:
dynamically computing the feedback bias for each calibration session and/or each calibration iteration based on (1) one or more variations in code word measurements corresponding to data stored in the memory cells, (2) a write time of the data stored within the memory cells, (3) a read adjustment updated and applied to the read level voltage in reading the stored data, or a combination thereof.

20. The method of claim 16, further comprising:
estimating a pattern between different values of the read level voltage and corresponding feedback values wherein the pattern is represented by data from previous calibration iterations, data from previous calibration sessions, total active time of the memory device, a number of memory access operations, or a combination thereof, wherein the pattern includes a sampled minimum level corresponding to a lowest error rate; and
dynamically computing the feedback bias based on the estimated pattern,
wherein the read level voltage is calibrated to a voltage level above the sampled minimum level based on the feedback bias.
